(19) United States
(12) Patent Application Publication
(10) Pub. No.: US 2019/0161829 A1
(43) Pub. Date: May 30, 2019

(54) PROCESS FOR PREPARATION OF THE INTERMETALLIC COMPOUND Nb3Sn BY MELT METALLURGICAL PROCEDURE

(71) Applicant: Heraeus Deutschland GmbH & Co. KG, Hanau (DE)

(72) Inventors: Bernd Spaniol, Hammersbach (DE); Stefan Csirak, Erlensee (DE); Markus Virgin, Bessenbach (DE); Markus Schultheis, Flieden (DE)

(21) Appl. No.: 16/197,173

(22) Filed: Nov. 20, 2018

(30) Foreign Application Priority Data
Nov. 28, 2017 (EP) 17204083.4

(51) Int. Cl. C22C 1/02; C22C 27/02

(52) U.S. Cl. CPC C22C 1/02; H01L 21/02194; C22C 27/02

(57) ABSTRACT

The invention relates to a process for preparation of the intermetallic compound Nb₃Sn by melt metallurgical procedure. The process comprises the steps of pressing Nb particles and Sn particles to form a start electrode, whereby the pressed start electrode is remelted in a vacuum in an electric arc, whereby a first moulded body is obtained. Alternatively, the process comprises the steps of remelting an Nb start electrode in an electric arc in a vacuum, whereby Sn particles are being introduced into the molten Nb forming during the remelting, whereby a first moulded body is obtained. The molar ratio of Nb and Sn is selected appropriately such that the first moulded body obtained contains at least 50% by weight of the intermetallic compound Nb₃Sn as the A15 phase as well as free Nb and/or Sn and inevitable impurities, if applicable.

This application claims the benefit of European patent application no. EP 17204083.4, filed Nov. 28, 2017, the entire contents of which are incorporated by reference herein.

The invention relates to a process for preparation of the intermetallic compound Nb₃Sn by melt metallurgical procedure. The invention also relates to an intermetallic compound that can be produced by said process.

Nb₃Sn is an intermetallic compound from the group of the niobium-tin compounds. The most well-known phases, aside from Nb₃Sn, are Nb₆Sn₅ and NbSn₂. Nb₃Sn crystallises in the so-called A15 phase and is known to be a type II superconductor with a transition temperature of 18.3 K. Due to this transition temperature, Nb₃Sn possesses clearly better electrical properties then niobium-titanium, but is also an extremely brittle material that cannot be processed directly into wires for superconducting coils. Therefore, ductile precursors are the basis for the practical use of the compound in superconducting wires and cables.

An example to be referred to here is the bronze process, which is based on a cylinder-shaped moulded body made of bronze. The bronze is pervaded by bore holes into which the rods made of specially doped niobium are inserted. The external surface of the bronze rod is covered by a thin tantalum coating and is jacketed with a copper matrix to improve the drawing properties. The wire drawn from this rod can then be coiled into any shapes, but is not superconducting. It attains this property only upon being heated to a temperature of approximately 700° C. During this process, tin from the bronze diffuses into the niobium wires. The annealing is terminated once the composition in the wires has reached Nb₃Sn. The tantalum barrier prevents tin from diffusing outwards into the copper jacket during the annealing process. After this treatment, the wires are superconducting, but are also mechanically very sensitive, the actual superconducting Nb₃Sn may break when the wires are bent even slightly.

In the production of cavity resonators for particle accelerators with high end energy, it is also advantageous to use superconducting materials such as Nb₃Sn. The shaping of the cavity resonator is crucial in this context, such that it is expedient to use computer-controlled additive processes for the production of components of this kind. For this purpose, large amounts of highly pure superconducting compounds are needed to generate the corresponding particles for processing in additive processes.

Specifically, highly pure Nb₃Sn in A15 phase can be used for producing the cavity resonators.

Nb₃Sn can be obtained by reacting the elements at 900 to 1000° C. or from NbSn₂ and niobium and a low fraction of Cu as a catalyst at 600° C. Alternatively, niobium(V) chloride and tin(II) chloride can be converted at temperatures below 1000° C. to produce Nb₃Sn, whereby gaseous hydrogen chloride is obtained as a side product.

EP 0 109 233 discloses a process for preparation of Nb₃Sn, in which a niobium halide is converted with liquid tin, whereby the niobium halide is used below its dissociation temperature and the product (Nb₃Sn) sediments as a precipitate in the reaction mixture.

The aforementioned processes usually are disadvantageous in that the generation of Nb₃Sn, i.e. niobium-tin as A15 phase, is difficult to control. Usually, more than insignificant amounts of other niobium-tin phases are obtained as side products and are subsequently difficult to separate from the main phase. Since the conversion often is not complete, large excesses of Sn need to be used, which in turn is associated with difficulties in the subsequent purification.

Accordingly, it is an object of the present invention to overcome the disadvantages of the prior art, at least in part.

It is another object of the present invention to provide a process that enables the preparation of the intermetallic compound Nb₃Sn at high purity and in large amounts, in particular on a kg scale.

It is another object of the present invention to provide a process for preparation of the intermetallic compound Nb₃Sn, by means of which the yield of Nb₃Sn can be controlled through the amounts of Nb and Sn added and in which the side products associated with the use of an excess of Nb or Sn are essentially pure Nb or pure Sn as accompanying products.

It is another object of present invention to provide a process for preparation of the intermetallic compound Nb₃Sn that generates essentially Nb₃Sn in the A15 phase as the product, whereby only insignificant or non-interfering amounts of other niobium-tin phases arise.

A contribution to solving at least one of the aforementioned objects is provided by the subject matters of the independent claims. The dependent claims are preferred embodiments of the present invention, which also make a contribution to solving at least one of the aforementioned objects. Features and details that are described in the context of the process according to the invention shall also apply in the context of the niobium-tin compound according to the invention, and vice versa.

A contribution to solving at least one of the aforementioned objects is provided by a process for preparation of the intermetallic compound Nb₃Sn by melt metallurgical procedure, whereby the process comprises the following steps:
i. Pressing Nb particles and Sn particles to form a start electrode, whereby the pressed start electrode is remelted in a vacuum in an electric arc, whereby a first moulded body is obtained or
ii. re-melting an Nb start electrode in a vacuum in an electric arc, whereby Sn particles are introduced into the molten Nb that forms in the process during the reforming, whereby a first moulded body is obtained, whereby the molar ratio of Nb and Sn is selected appropriately such that the first moulded body obtained contains at least 50% by weight of the intermetallic compound Nb₃Sn as A15 phase and, if applicable, free Nb and/or Sn and inevitable impurities.

Preferably, the added weight fractions of Sn and Nb add up to 100% by weight, meaning that no further metals or other elements are added in the process according to the invention.

According to the first alternative of the process according to the invention, Nb particles and Sn particles at a predefined stoichiometric ratio are pressed to form a start electrode. The pressed start electrode is remelted using a vacuum-electric arc remelting procedure (vacuum arc remelting—VAR), whereby a first moulded body is obtained.

According to the second alternative of the process according to the invention, a pure niobium start electrode is remelted using a vacuum-electric arc remelting procedure. During the remelting, a defined amount of tin is added to the molten Nb that is being formed, whereby a first moulded body is obtained. Either a melted cylindrical Nb stud or an electrode pressed from Nb chips is used as Nb starting electrode.

In both alternatives, the molar ratio of Nb and Sn (or vice versa) is selected appropriately such that the moulded body that is obtained contains at least 50% by weight of the intermetallic compound Nb₃Sn as the A15 phase. Preferably, the molar ratio of Nb and Sn is selected appropriately such that the moulded body that is obtained contains at least 75% by weight, more preferably at least 90% by weight, even more preferably at least 95% by weight, yet more preferably at least 99% by weight and even yet more preferably at least 99.5% by weight of the intermetallic compound Nb₃Sn as the A15 phase.

If an excess of Nb or Sn is used, the process according to the invention produces essentially Nb₃Sn as the main product as well as free Nb or Sn as accompanying products aside from inevitable impurities.

Inevitable impurities are, in particular, accompanying elements that are introduced with the raw materials. Said impurities are usually contained in amounts of less than 0.1% by weight in the direct product of the process, preferably in amounts of less than 1000 mg/kg, more preferably in amounts of less than 100 mg/kg, each relative to the total amount of the impurity in the direct product of the process.

Further inevitable impurities are niobium-tin compounds that are not present in the A15 phase, i.e. not as Nb₃Sn. Specifically, these are Nb₆Sn₅ and NbSn₂. These products or intermetallic compounds are also called undesired side products. Preferably, each of these compounds individually is contained in the product of the process in an amount of less than 5% by weight, more preferably in an amount of less than 1% by weight, and even more preferably in an amount of less than 0.1% by weight.

It has been found, surprisingly, that the melt metallurgy process according to the invention can be used not only for the production of Nb₃Sn on a kilogram scale, but that Nb₃Sn in the A15 phase is formed predominantly and only low concentration of non-desirable niobium-tin compounds are contained in the direct product of the process.

According to a preferred embodiment of the invention, the process according to the invention comprises, in addition, the following steps:
a. Mechanical disintegration of the first moulded body to form particles,
b. Mixing of the particles obtained in step a. with Nb particles and/or Sn particles and pressing the mixture to form a second moulded body, whereby the fraction, in the second moulded body, of the particles obtained in step a. is at most 80% by weight;
c. Remelting the second moulded body in an electric arc in a vacuum, whereby a third moulded body is obtained;

whereby the molar ratio of Nb and Sn is selected appropriately such that the third moulded body obtained contains at least 70% by weight of the intermetallic compound Nb₃Sn as A15 phase and, if applicable, free Nb and/or Sn and inevitable impurities.

The preferred product of the process, Nb₃Sn, can be obtained at higher purity by means of these additional process steps. The amount of undesirable niobium-tin compounds can be reduced even further by this means.

According to this embodiment, the first moulded body that is obtained is disintegrated mechanically to form particles. The disintegrated particles are mixed as homogeneously as possible with Nb particles and/or Sn particles and are pressed to form a second moulded body. The fraction of particles from the first moulded body that are used here should be no more than 80% by weight. Due to the fraction of Nb₃Sn being so high, the material of the first moulded body is so brittle that a minimum fraction of 20% by weight of ductile material is needed in order to obtain a mechanically stable second moulded body. Said second moulded body is subsequently remelted using a vacuum-electric art remelting procedure, whereby a third moulded body is obtained.

The molar ratio of Nb and Sn is selected appropriately with reference to the final product such that the third moulded body that is obtained contains at least 70% by weight of the intermetallic compound Nb₃Sn as the A15 phase. Accordingly, starting from the first moulded body, a sufficient amount of Nb or Sn is added in the production of the second moulded body such that at least 70% by weight Nb₃Sn at a stoichiometric ratio of 3 niobium to 1 tin is generated and, moreover, essentially free Nb or free Sn are obtained in the product.

Preferably, the molar ratio of Nb and Sn is selected appropriately such that the moulded body that is obtained contains at least 85% by weight, more preferably at least 95% by weight, even more preferably at least 99% by weight, yet more preferably at least 99.5% by weight and even yet more preferably at least 99.9% by weight of the intermetallic compound Nb₃Sn as the A15 phase.

If applicable, the third moulded body contains inevitable impurities.

Inevitable impurities are, in particular, accompanying elements that are introduced with the raw materials. The second remelting in an electric arc in a vacuum allows the amount of said impurities to be reduced further. Said impurities are contained in the product of the process after the second remelting in amounts of less than 0.05% by weight, preferably in amounts of less than 50 mg/kg, each relative to the total amount of the impurity in the product of the process.

Further inevitable impurities are niobium-tin compounds that are not present in the A15 phase, i.e. not as Nb₃Sn. Specifically, these are Nb₆Sn₅ and NbSn₂. Preferably, each of these compounds is contained in the product of the process after the second remelting in an amount of less than 1% by weight, more preferably in an amount of less than 0.5% by weight and yet more preferably in an amount of less than 0.05% by weight.

It is another advantage of a second remelting that the second moulded body already comprises a significant fraction of Nb₃Sn, which has a lower melting point (2150° C.) than pure niobium (2477° C.). The high vapour pressure of tin is less problematic at a lower working temperature of the molten material since there is less uncontrolled evaporation of the tin.

In a preferred embodiment of the invention, the Sn particles according to step ii. are introduced successively into the molten Nb that is being formed.

Successive introduction shall be understood to mean that the particles are not added in one step into the molten Nb that is being formed, but in small aliquots over an extended period of time. Said successive introduction of the Sn particles into the molten Nb that is being formed minimises Sn evaporation losses, which improves the stoichiometric control over the reaction and therefore Nb₃Sn in the A15 phase is formed predominantly.

In a preferred embodiment of the invention, the particles obtained from the first moulded body have a mean cross-sectional area that is at most one fourth of the cross-sectional area of the second moulded body. Preferably, the mean cross-sectional area of the particles of the first moulded body is at most one tenth of the cross-sectional area of the second moulded body, more preferably one hundredth, and even more preferably one thousandth of the cross-sectional area of the second moulded body.

In order to make the particles easier to process to form the second moulded body, the first moulded body must be mechanically disintegrated appropriately such that the miscibility of the particles obtained from the first moulded body with additional Nb particles and/or Sn particles is assured such that a mechanically stable second moulded body is obtained. In this context, the second moulded body is the more stable, the smaller the mean cross-sectional area of the particles obtained from the first moulded body is.

A further embodiment of the process according to the invention is characterised in that the fraction of Sn particles in the total amount before the remelting to form the first moulded body is 30.0% by weight to 33.0% by weight.

Accordingly, a Nb fraction of 67.0 to 70.0% by weight is used such that the two weight fractions add up to 100% by weight. A Sn fraction of 30.0 to 33.0% by weight corresponds to a Sn fraction of 25.2 at. % (atom percent) to 27.8 at. %. A Nb fraction of 67.0 to 70.0% by weight corresponds to a Nb fraction of 72.1 at. % to 75.3 at. %. Pure Nb₃Sn has an Sn fraction of 25 at. % and a Nb fraction of 75 at. %. According to said embodiment, Sn is easily used in over-stoichiometric amounts. This balances out Sn losses during the production of the first moulded body. Said losses can occur since the melting points of Nb and Sn differ strongly, for example through evaporation of tin during the melting of the start electrode to form the first moulded body or through evaporation of tin during the remelting of the second moulded body to form the third moulded body.

A further embodiment of the process according to the invention is therefore characterised in that the fraction of Sn particles in the second moulded body before the remelting to form the third moulded body is 30.0% by weight to 33.0% by weight.

The specifications provided with regard to the composition of the start electrode for production of the first moulded body shall apply analogously to the second moulded body that is being remelted to form the third moulded body. The amount of tin and/or niobium that needs to be added to the particles obtained from the first moulded body in order to set a weight fraction of 30.0% by weight to 33.0% by weight can be determined, for example, by elemental analysis of a representative sample of the particles from the first moulded body. If this composition is known, Sn particles and/or Nb particles can be admixed accordingly such that the desired weight ratio of Nb and Sn is obtained.

Another embodiment of the process according to the invention is characterised in that the vacuum during the re-melting comprises a partial pressure of no more than 500 mbar. Preferably, the vacuum during the remelting comprises a partial pressure from 100 to 300 mbar, particularly preferably a partial pressure from 180 to 220 mbar, and more preferably a partial pressure of 200 mbar.

This applies both to the vacuum applied during the remelting of the start electrode to form the first moulded body and for the vacuum during the remelting of the second moulded body to form the third moulded body. It has been found that the tin evaporation rate can be reduced significantly through the use of a moderate vacuum. Because the melting temperatures of Nb (2477° C.) and Nb₃Sn (2150° C.) are high, uncontrolled evaporation of tin (melting temperature 262° C.; boiling temperature 2620° C.) in a vacuum can occur, but can be prevented by the application of a moderate vacuum. The partial pressure used here counteracts the high vapour pressure of tin. Working with a relatively high partial pressure during the remelting is of advantage especially when an over-stoichiometric amount of tin is being used.

Another embodiment of the process according to the invention is characterised in that the remelting in an electric arc in a vacuum is carried out in a protective gas that is inert with respect to Nb and Sn.

The particular purpose of using a protective gas is to prevent the oxidation of Nb and Sn to the corresponding oxides, for example tin(II) oxide, tin(IV) oxide or niobium(V) oxide. The formation of metal oxides would have a negative effect on the magnetic and electrical properties of Nb₃Sn. Moreover, the oxides thus formed would be difficult to separate from the direct product of the process.

Another embodiment of the process according to the invention is characterised in that a noble gas is used as protective gas.

Amongst the noble gases, in particular helium is preferred as protective gas. It has been found, surprisingly, that the use of helium in the remelting process in an electrical arc in a (partial) vacuum is associated with the formation of little to no plasma, whereas the use of argon led to a significant formation of plasma. The formation of plasma can lead to local uncontrolled overheating in the molten material during the melting process which results in a less well-controlled formation of Nb₃Sn, which in turn can favour the formation of undesired side products.

Another embodiment of the process according to the invention is characterised in that the molar ratio of Nb and Sn is selected appropriately such that the first moulded body and/or the third moulded body contain 1 to 5% by weight free Sn, whereby the rest of the moulded body contains essentially Nb₃Sn as the A15 phase.

The formation of a product of the process with a fraction of 1 to 5% by weight of free Sn is advantageous if the processing of the material requires a high energy input. One example of such a case is the further processing of the product of the process to form a powder or the use of the powder in an additive production process. Said processes use high energy rays in the form of laser or electron beams. The spot-wise high energy input can partially decompose the intermetallic compound Nb₃Sn, due to which small amounts of Sn make get lost by evaporation. For this reason, it is of advantage in a preferred embodiment of the invention for the immediate product of the process to contain free amounts of Sn. Said free Sn is then evaporated preferably by the laser or electron beam due to its melting point being lower, such that smaller amounts of Nb₃Sn are decomposed, which leads to the product produced by additive production having improved impurity.

Another embodiment of the process according to the invention is characterised in that the first and/or third moulded body is/are taken up into a container, which is provided with an electrically insulating layer on its inside, during the remelting.

Due to this measure, electric arc discharges on the side are reduced and/or minimised, in particular in the case, in which Sn particles are being introduced during the remelting into the forming molten Nb during the formation of the first moulded body.

In this context, the electrically insulating layer is particularly preferred to be a metal oxide layer. Examples of suitable metal oxides are titanium(IV) oxide and niobium(V) oxide. For this purpose, the inside of the water-cooled copper crucible taking up the molten material is preferably coated with one of the aforementioned metal oxides. For example, a water-based titanium(IV) oxide dispersion is suitable for this purpose.

A contribution to solving at least one of the aforementioned objects is provided by an intermetallic niobium-tin compound that can be obtained by a process according to any one of the aforementioned embodiments. The intermetallic niobium-tin compound contains Nb₃Sn as its main component, the intermetallic compound contains at least 50% by weight pure Nb₃Sn in the A15 phase, whereby free Nb and free Sn as well as other inevitable impurities may be present in the intermetallic compound.

An embodiment of the intermetallic niobium-tin compound is characterised in that the fraction of A15 phase is at least 95% by weight. Accordingly, the intermetallic niobium-tin compound preferably contains at least 95% by weight Nb₃Sn in the A15 phase, more preferably at least 99% by weight, and even more preferably at least 99.5% by weight.

An embodiment of the intermetallic niobium-tin compound is characterised in that the Nb₆Sn₅ fraction of the composition is no more than 1% by weight, preferably no more than 0.5% by weight, and even more preferably no more than 0.1% by weight.

An embodiment of the intermetallic niobium-tin compound is characterised in that the NbSn₂ fraction of the composition is no more than 1% by weight, preferably is no more than 0.5% by weight, and more preferably is no more than 0.1% by weight.

Vacuum Arc Remelting Process

A “vacuum-electric arc remelting process” or “remelting in an electric arc in a vacuum”, also known as “vacuum arc remelting” (VAR), is a process that is known to a person skilled in the art for controlled solidification of metals, alloys, and intermetallic compounds. In the course of the process, a consumable electrode with a rectangular cross-section is remelted in a water-cooled copper melting crucible of a furnace. According to the invention, the consumable electrode can be the start electrode or the second moulded body. The furnace is being evacuated and a direct current art is being ignited between the electrode (cathode) and the so-called starter material on the bottom of the melting crucible (anode), also called “bottom protection”. In the process according to the invention, Nb₃Sn particles are used as bottom protection. The electric arc heats both the starting material on the bottom of the melting crucible and the tip of the electrode, which both need to be melted. When the electrode tip starts to be consumed, liquid molten material drips into the melting crucible arranged below it and there, according to the invention, forms the first or third moulded body. The process maintains a pool of liquid molten material that forms a transitional area toward a fully solidified ingot. The diameter of the melting crucible is larger than the diameter of the start electrode or of the second moulded body. Therefore, the steadily shrinking electrode can be moved downwards in the direction of the anode surface in order to maintain a constant mean distance between the electrode tip and the anode pool. The mean distance between the electrode tip and the pool surface consisting of liquid metal is called “electrode distance”.

To the same degree, to which cooling water dissipates heat from the wall of the melting crucible, the liquid molten material solidifies in the vicinity of the wall. A solid layer of material that solidifies on the wall of the melting crucible in the vicinity of the pool surface is called “edge”. Complete solidification of material proceeds at a certain distance below the molten pool surface, whereby a completely dense ingot of intermetallic compound is produced.

Volatile impurities evaporate during the VAR process. In the spirit of the process according to the invention, Sn can also be considered to be volatile, which is the reason to preferably not work with a vacuum, but with a partial vacuum in the present case in order to counteract the high vapour pressure of tin. The vapours of volatile elements deposit on cold surfaces during the VAR process, for example on the surface of a melting crucible wall immediately above the edge of solidifying material.

### Vacuum

In the spirit of the invention, the term “vacuum” shall be understood to mean working under reduced air pressure. Preferably, this means a pressure of less than 500 mbar, more preferably of less than 300 mbar, or 200 mbar or 50 mbar or 10 mbar or less than 1 mbar.

### Molar Ratio

According to the invention, “molar ratio” shall be understood, specifically, to be the ratio of Nb and Sn used in the process described herein, each in units of “mol” or “equivalents”. For example, if the molar ratio of Nb and Sn of 3:1 is used, 100 percent of one mol of the intermetallic compound Nb₃Sn can be formed. If a molar ratio of Nb and Sn of 4:1 is used, one mol of intermetallic compound Nb₃Sn can be formed theoretically, whereby one mol of free Nb would remain in the mixture. According to the invention, the molar ratio of Nb and Sn is selected appropriately such that a defined minimum amount of pure Nb₃Sn, for example at least 50% by weight or at least 70% by weight, and, as “residue”, essentially free Nb or Sn as well as inevitable impurities are present in the product composition.

In this context, “over-stoichiometric” shall be understood to mean that a larger amount of Nb or Sn is added then would be required for stoichiometric formation of Nb₃Sn. According to the above-mentioned example with 4 mol Nb and 1 mol Sn, and over-stoichiometric amount of Nb is used, since only 3 mol of Nb are required when 1 mol of Sn is used to form 1 mol of Nb₃Sn.

### Particles

By definition, “particles” shall be understood to be solid particles that are present in different form or shape and can be pressed to form a moulded body, whereby the moulded body comprises a significantly larger mean cross-sectional area than an individual particle. Examples of particle shapes that are used according to the invention include spherical particles, granules (grains), flakes, and chips.

### Tin, Niobium, Niobium-Tin, Nb₃Sn, and Intermetallic Compound

According to the invention, “Sn” or “tin” shall be understood to be the element tin in its metallic form. According to the invention, “Nb” or “niobium” shall be understood to be the element niobium in its metallic form.

“Niobium-tin” shall be understood to be a generic term covering all known and stable intermetallic niobium-tin compounds, regardless of their stoichiometric composition and the type of crystal lattice.

“Nb₃Sn” shall be understood to be an intermetallic compound consisting of 3 niobium atoms and 1 tin atom, whereby said intermetallic compound is present essentially crystalline in the A15 phase.

According to the invention, “intermetallic compound” can mean more than one intermetallic compound with a defined stoichiometric composition per se. In the spirit of the invention, free metals, in particular free Nb and/or Sn as well as alloy components and inevitable impurities may be contained in the intermetallic compound. Accordingly, the intermetallic compound can just as well be a composition that contains at least one intermetallic compound as such.

### EXEMPLARY EMBODIMENTS

Exemplary embodiments of the invention shall be illustrated in the following on the basis of one schematic figure and two diagrams, though without limiting the scope of the invention. In the figures,

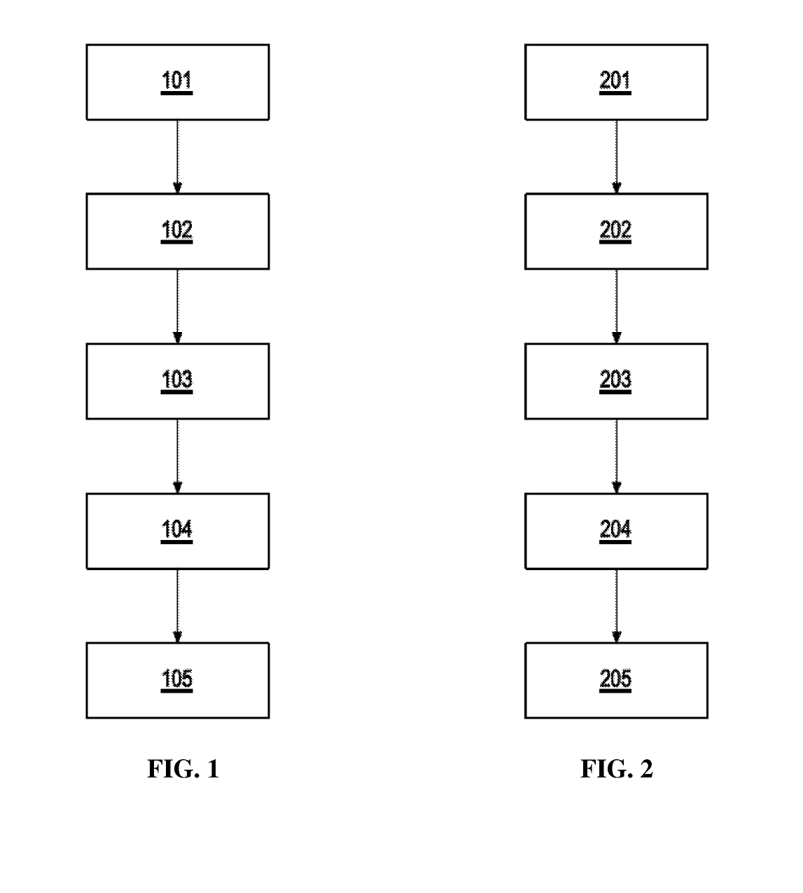

FIG. 1 shows a schematic depiction of a first alternative of the process according to the invention in the form of a flow diagram;

FIG. 2 shows a schematic depiction of a second alternative of the process according to the invention in the form of a flow diagram;

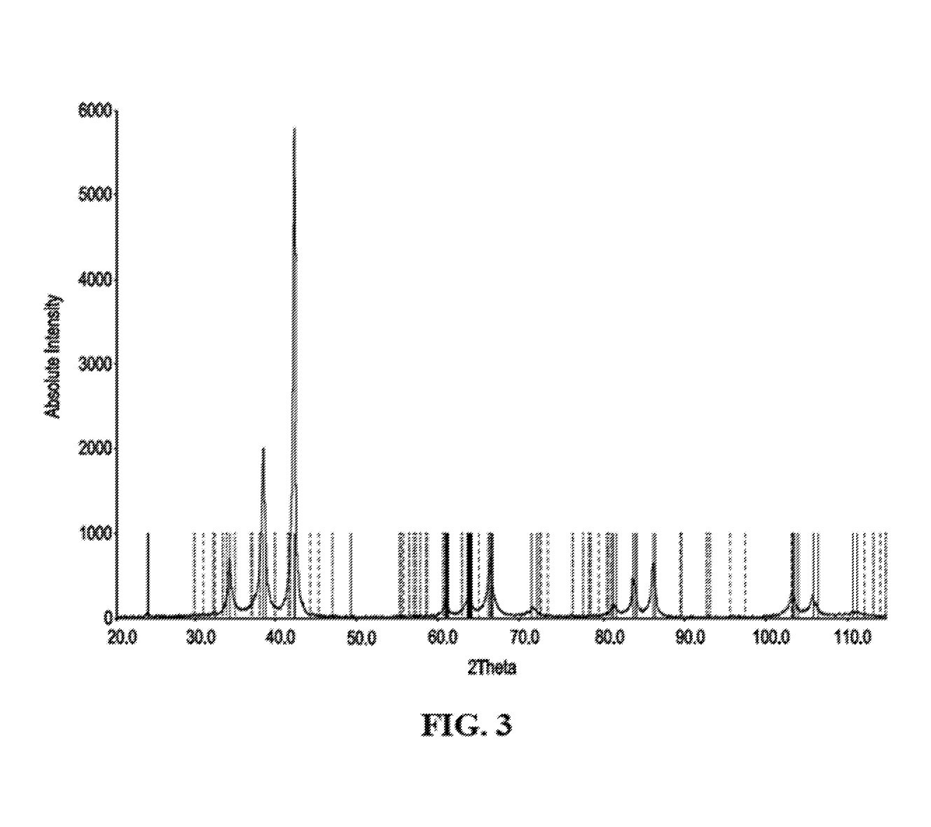

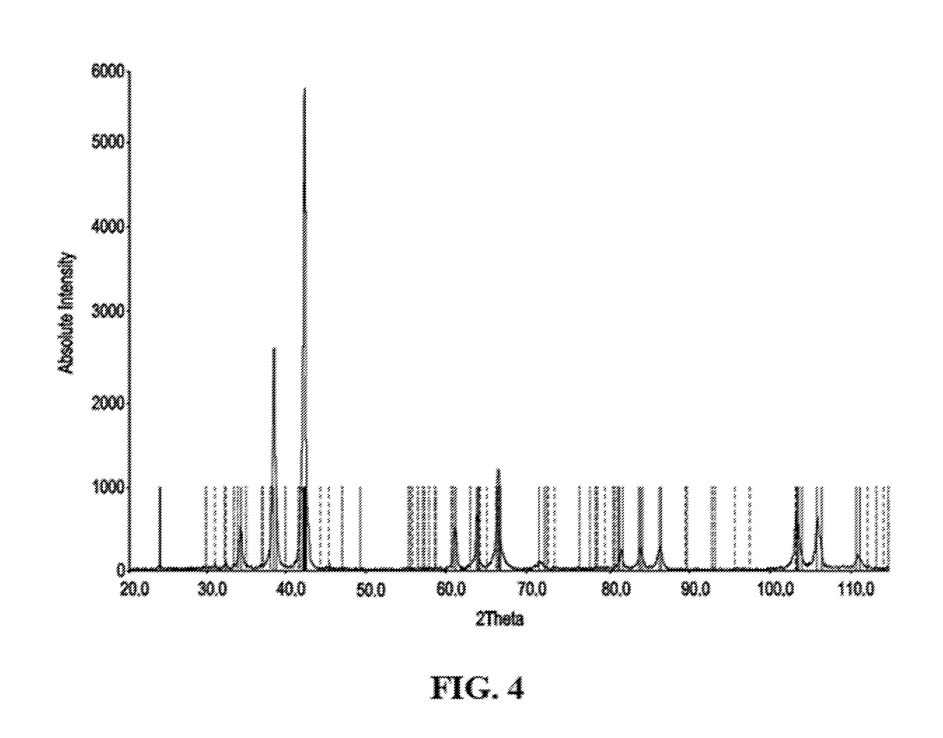

FIG. 3 shows an x-ray diffractometric analysis of the product according to the process based on a batch with a stoichiometric composition;

FIG. 4 shows an x-ray diffractometric analysis of the product according to the process based on a batch with an excess of tin.

FIG. 1 shows a schematic depiction of a first alternative of the process according to the invention in the form of a flow diagram. Initially, in a first step 101, Nb particles and Sn particles are pressed to form a start electrode. For example, Nb chips and tin granules (metal grains) can be used in this context. In a subsequent step 102, the start electrode is remelted in an electric arc in a vacuum as a consumable electrode, whereby a first moulded body is obtained as first product after the molten material has cooled. Said first moulded body already comprises Nb₃Sn as the main phase (A15 phase). To improve the purity of the product even more, the first moulded body can be mechanically disintegrated to form particles in a further process step 103. The Nb₃Sn particles thus obtained are subsequently mixed with Nb particles and Sn particles in a step 104 and are pressed to form a second moulded body. The Nb₃Sn particles thus obtained are remelted again in an electric arc in a vacuum in a step 105, whereby a third moulded body made of Nb₃Sn is obtained.

FIG. 2 shows a schematic depiction of a second alternative of the process according to the invention in the form of a flow diagram. In a first step 201, an ingot made of Nb is provided as consumable electrode. In a subsequent step 202, the electrode is remelted in an electric arc in a vacuum, whereby Sn particles are being trickled into the forming molten material during this remelting process. For example, Sn granules (metal grains) can be used for the trickling. The product of remelting, the first moulded body, already comprises Nb₃Sn as the main phase (A15 phase). To further improve the purity of the product, the first moulded body can be mechanically disintegrated to form particles in a further process step 203. The Nb₃Sn particles thus obtained are subsequently mixed with Nb particles and Sn particles in a step 204 and are pressed to form a second moulded body. The Nb₃Sn particles thus obtained are remelted again in an electric arc in a vacuum in a step 205, whereby a third moulded body made of Nb₃Sn is obtained.

### Example 1

The production according to the first alternative of the process according to the invention through the use of a single remelting process is illustrated in the following based on a concrete exemplary embodiment.

Nb chips and Sn granules were used initially to produce a pressed electrode with dimensions of 35×32×480 mm in a rectangular die using a pressing force of 500 t. The weight of the electrode thus obtained was 3.74 kg. A total of 100 g of Nb₃Sn particles were used as bottom protection in the vacuum-arc remelting process. The electrode was remelted in an electric arc furnace as a consumable electrode in a water-cooled copper crucible with an internal diameter of 80 mm. In order to minimise the evaporation of Sn, the partial pressure was 200 mbar. The copper crucible was insulated on the inside, in order to prevent lateral electric arc discharges. Argon was used as the partial pressure gas. There was a slight formation of plasma during the melting, during which the melting power was 70 kW (2.0 kA/35 V). The weight of the ingot produced by melting, i.e. of the first moulded body, was 3.79 kg. Accordingly, the total loss of Sn was 50 g.

In an improved batch, helium rather than argon was used as the partial pressure gas.

A pressed electrode made of Nb and Sn with a total weight of 3.77 kg was used in the batch. In this case, a first moulded body with a total weight of 3.80 kg was obtained. The Sn loss was 70 g. Due to the use of helium as the partial pressure gas, the formation of a plasma was prevented, i.e. no formation of plasma was observed during the remelting process.

### Example 2

The production according to the second alternative of the process according to the invention through the use of a single remelting process is illustrated in the following based on a concrete exemplary embodiment.

A niobium rolled section rod with a width across flaps of 32 mm and a length of 480 mm was remelted as a consumable electrode in an electric arc furnace. The weight of the niobium electrode was 3.57 kg. A total of 100 g of Nb₃Sn were used as bottom protection. To generate the intermetallic composition Nb₃Sn during the melting, 1.64 kg tin granules (metal grains) were semi-continuously trickled into the molten material. After each 20 mm of travel of the electrode, 68.3 g of tin granules were added into the molten niobium using a rotary disk conveyor. The partial pressure during the melting and trickling process was 200 mbar, whereby helium was used as the partial pressure gas. The use of a partial pressure of 200 mbar and helium again served to minimise the evaporation of Sn and the formation of a plasma. In order to prevent lateral electric arc discharges, an inside-cooled copper crucible and a constantly rotating stirring field were used. The melting power was 70 kW (2.0 kA/35 V). The weight of the ingot produced by melting, i.e. of the first moulded body, was 5.14 kg. The Sn loss was 70 g.

### Example 3

In the following, the further processing of the moulded body produced according to the first alternative (Example 1) or second alternative (Example 2) of the process according to the invention through the use of a second remelting process is illustrated in more detail.

The moulded body obtained according to either one of the aforementioned batches was extremely brittle and was therefore easy to break mechanically. Accordingly, a jaw crusher was used to produce particles with a maximum dimension of 5 mm from the first moulded body. For homogenisation, the particles that could be pressed to form a second moulded body were mixed by hand in a metal tub.

Subsequently a pressed electrode, i.e. the second moulded body, with dimensions of D×35×480 mm (D=variable thickness) was produced with a pressing force of 500 t to produce highly pure Nb₃Sn in the A15 phase by melting. The weight of the pressed electrode was 5000 g.

Depending on whether or not a stoichiometric or over-stoichiometric (Sn excess) composition was used, the pressed electrode or the second moulded body had the following composition:

| | | Fraction of | | |
|---|---|---|---|---|
| | | particles from | Fraction | Fraction |
| | | first moulded | of Nb | of Sn |
| | Ratio of | body | chips | granules |
| Batch no. | Nb:Sn | (wt. %) | (wt. %) | (wt. %) |
| 1 | stoichiometric | 50 | 35 | 15 |
| 2 | Sn excess | 50 | 33 | 17 |

The pressed electrodes or second moulded body according to batch no. 1 or 2 were produced by melting in an electric arc furnace as the consumable electrode. The partial pressure during the melting process was 200 mbar, which, as before, served to minimise the evaporation of Sn. Helium was used as the partial pressure gas in order to prevent the formation of plasma, as before. An inside-insulated copper crucible was used in order to prevent lateral electric arc discharge. Moreover, a constantly rotating stirring field was used to further minimise lateral electric arc discharges. The melting power was 70 kW (2.0 kA/35 V).

The weight of the ingot produced by melting, i.e. of the third moulded body, according to batch 1 was 4.91 kg. The weight loss of tin was 90 g.

The weight of the ingot produced by melting, i.e. of the third moulded body, according to batch 2 was 4.93 kg. The weight loss of tin was 87 g.

Random fragments of the moulded body obtained were used for preparation of the subsequent analyses. One fragment was machined such to be planar in one place for x-ray diffractometric analysis. The fragment selected for chemical analysis was mechanically disintegrated.

FIG. 3 shows an x-ray diffraction analysis (X-ray diffraction—XRD) of the ingot or third moulded body according to batch 1. The vertical lines along the x-axis show reference signals, i.e. the expected positions of the signals for Nb₃Sn in the A15 phase (solid lines), NbSn₂ (dotted lines) or free Sn (dashed lines). The signal intensity of the individual component of the sample is expressed by the peaks at the corresponding reference positions. It is evident in this context that the sample according to batch 1 essentially contains peaks in the area of the solid reference lines, i.e. peaks to be associated with Nb₃Sn in the A15 phase. The peaks for NbSn₂ and free Sn are very weak and/or hardly detectable in the noise of the individual signals.

FIG. 4 shows an x-ray diffraction analysis (X-ray diffraction—XRD) of the ingot or third moulded body according to batch 2, in which an excess of Sn was used. As before, the signals and/or peaks of Nb₃Sn in the A15 phase predominate, whereas the peaks to be assigned to pure Sn and NbSn₂ are rather weak.

Accordingly, the x-ray diffractometric analyses demonstrate that the process according to the invention is well-suited for preparation of pure Nb₃Sn in A15 phase.

The following table shows the composition of the products obtained according to Example 1 and Example 3 according to a chemical analysis. For Example 3, the two batches according to batch 1 and batch 2 are shown.

| Example no. | Nb (wt. %) | Sn (wt. %) |
|---|---|---|
| Example 1 | 71.1 | 28.8 |
| Example 3, batch | 70.6 | 29.3 |
| 1 (stoichiometric) | | |
| Example 3, batch | 69.0 | 30.9 |
| 2 (Sn excess) | | |

Ideally, pure Nb₃Sn has a content of 70.1% by weight and an Sn content of 29.9% by weight.

1. A process for preparation of the intermetallic compound Nb₃Sn by a melt metallurgical procedure, the process comprising:
i. Pressing Nb particles and Sn particles to form a start electrode, whereby the pressed start electrode is remelted in a vacuum in an electric arc, whereby a first moulded body is obtained or
ii. Re-melting an Nb start electrode in a vacuum in an electric arc, whereby Sn particles are introduced into the molten Nb that forms in the process during the reforming, whereby a first moulded body is obtained,
whereby the molar ratio of Nb and Sn is selected appropriately such that the first moulded body obtained contains at least 50% by weight of the intermetallic compound Nb₃Sn as A15 phase and, if applicable, free Nb and/or Sn and inevitable impurities.

2. The process of claim 1, further comprising:
a. Mechanical disintegration of the first moulded body to form particles;
b. Mixing of the particles obtained in step a. with Nb particles and/or Sn particles and pressing the mixture to form a second moulded body, whereby the fraction, in the second moulded body, of the particles obtained in step a. is at most 80% by weight;
c. Remelting the second moulded body in an electric arc in a vacuum, whereby a third moulded body is obtained;
whereby the molar ratio of Nb and Sn is selected appropriately such that the third moulded body obtained contains at least 70% by weight of the intermetallic compound Nb₃Sn as the A15 phase and, if applicable, free Nb and/or Sn and inevitable impurities.

3. The process of claim 1, wherein, according to step ii., the particles are introduced successively into the forming molten Nb material.

4. The process of claim 2, wherein the particles obtained from the first moulded body comprise a mean cross-sectional area that is at most one fourth of the cross-sectional area of the second moulded body.

5. The process of claim 1, wherein the fraction of Sn particles in the total amount before the remelting to form the first moulded body is 30.0% by weight to 33.0% by weight.

6. The process of claim 1, wherein the fraction of Sn in the second moulded body before the remelting to form the third moulded body is 30.0% by weight to 33.0% by weight.

7. The process of claim 1, wherein the vacuum during the remelting comprises a partial pressure of no more than 500 mbar.

8. The process of claim 1, wherein the remelting in an electric arc in a vacuum is carried out in a protective gas that is inert with respect to Nb and Sn.

9. The process of claim 8, wherein a noble gas is used as the protective gas.

10. The process of claim 9, wherein helium is used as the protective gas.

11. The process of claim 1, wherein the molar ratio of Nb and Sn is selected appropriately such that the first moulded body and/or the third moulded body contains 1 to 5% by weight of free Sn, whereas the remainder of the moulded body essentially comprises Nb₃Sn in the A15 phase.

12. The process of claim 1, wherein the first and/or third moulded body is/are taken up into a container, which is provided with an electrically insulating layer on its inside, during the remelting.

13. The process of claim 12, wherein the electrically insulating layer is a metal oxide layer.

14. An intermetallic niobium-tin compound, obtainable through a process according to claim 1.

15. An intermetallic niobium-tin compound according to claim 14, wherein the fraction of A15 phase is at least 95% by weight.

16. An intermetallic niobium-tin compound according to claim 14, wherein the fraction of Nb₆Sn₅ in the composition is no more than 1% by weight.

17. An intermetallic niobium-tin compound according to claim 14, wherein the fraction of NbSn₂ in the composition is no more than 1% by weight.
